(19) United States
(12) Patent Application Publication
(10) Pub. No.: US 2012/0092195 A1
(43) Pub. Date: Apr. 19, 2012

(54) Protective Device for an Electronic Apparatus

(75) Inventor: Jia-Bao Lin, Taichung Hsien (TW)

(73) Assignee: SUNREX TECHNOLOGY CORP., Taichung Hsien (TW)

(21) Appl. No.: 12/903,453

(22) Filed: Oct. 13, 2010

(51) Int. Cl. H03K 17/94; B65D 85/00

(52) U.S. Cl. 341/22; 206/320

(57) ABSTRACT

A protective device for an electronic apparatus includes: a base unit including a base plate having a base front end portion and a base rear end portion; a cover plate including a cover front end portion connected swingably to the base unit and disposed above the base front end portion, and a cover rear end portion disposed above the base rear end portion, the cover plate being swingable relative to the base unit to move the cover rear end portion toward or away from the base rear end portion; two fence members cooperating with the cover plate and the base plate to define a receiving space for receiving the electronic apparatus, the receiving space having an opening between the base and cover rear end portions when the cover rear end portion moves away from the base rear end portion; and an input unit disposed on the cover plate.

### BACKGROUND OF THE INVENTION

1. Field of the Invention

This invention relates to a protective device for an electronic apparatus, more particular to a protective device for an electronic apparatus with an ergonomic design.

2. Description of the Related Art

Referring to FIG. 1, a protective device for an electronic apparatus as disclosed in Taiwanese Patent No. 557688 comprises a first portion 12 for mounting a handheld electronic apparatus 11 that has a display panel 111, and a second portion 19 adjacent to the first portion 12 and disposed with an input unit 13. The input unit 13 has a membrane keyboard 131 and a touchpad 132. The handheld electronic apparatus 11 can be protected from being damaged by the first portion 12 and the second portion 14, and is able to receive input data from a user through the input unit 13.

Since the display panel 111 of the handheld electronic apparatus 11 is parallel to the first portion 12, and since the conventional protective device is disposed horizontally on a surface when in use, the display panel 111 is parallel to the surface and is inconvenient for the user's viewing, and the membrane keyboard 131 of the input unit 13 is likewise parallel to the surface and cannot be operated by the user in a more ergonomic way.

### SUMMARY OF THE INVENTION

Therefore, the object of the present invention is to provide a protective device that is able to receive an electronic apparatus and that is capable of varying an inclined angle of an input unit connected to the electronic apparatus with respect to the user in conformity with ergonomics.

Accordingly, a protective device for an electronic apparatus of the present invention comprises: a base unit including a base plate having a base front end portion, a base rear end portion, a base left end portion, and a base right end portion; a cover plate disposed above the base plate, and including a cover front end portion connected swingably to the base unit and disposed above the base front end portion, a cover rear end portion disposed above the base rear end portion, a cover left end portion disposed above the base left end portion, and a cover right end portion disposed above the base right end portion, the cover plate being swingable relative to the base unit to move the cover rear end portion toward or away from the base rear end portion; two fence members, one of which is connected between the base and cover left end portions and the other of which is connected between the base and cover right end portions, the fence members cooperating with the cover plate and the base plate unit to define a receiving space for receiving the electronic apparatus, the receiving space having an opening between the base and cover rear end portions when the cover rear end portion moves away from the base rear end portion; and an input unit disposed on the cover plate.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a perspective view showing a conventional protective device for an electronic apparatus;

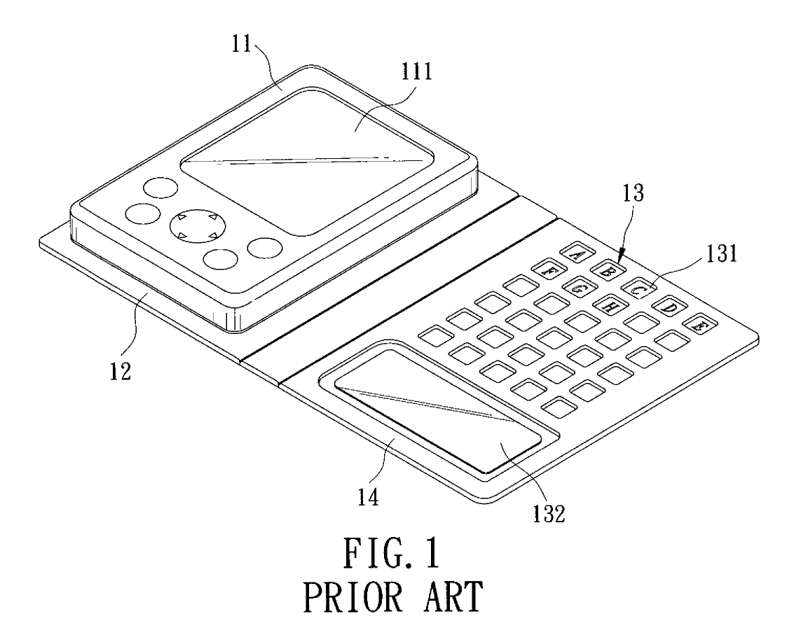

FIG. 2 is a perspective view of the preferred embodiment of a protective device for an electronic apparatus according to this invention;

FIG. 3 is a front view of the preferred embodiment;

FIG. 4 is a bottom view of the preferred embodiment;

FIG. 5 is a schematic longitudinal sectional view of the preferred embodiment, showing a cover plate swung away from a base plate;

FIG. 6 is a perspective view of the preferred embodiment, showing the cover plate swung toward and inclined with respect to the base plate;

FIG. 7 is a schematic longitudinal sectional view of the preferred embodiment shown in FIG. 6; and

FIG. 8 is a fragmentary cross sectional view of the preferred embodiment.

### DETAILED DESCRIPTION OF THE PREFERRED EMBODIMENTS

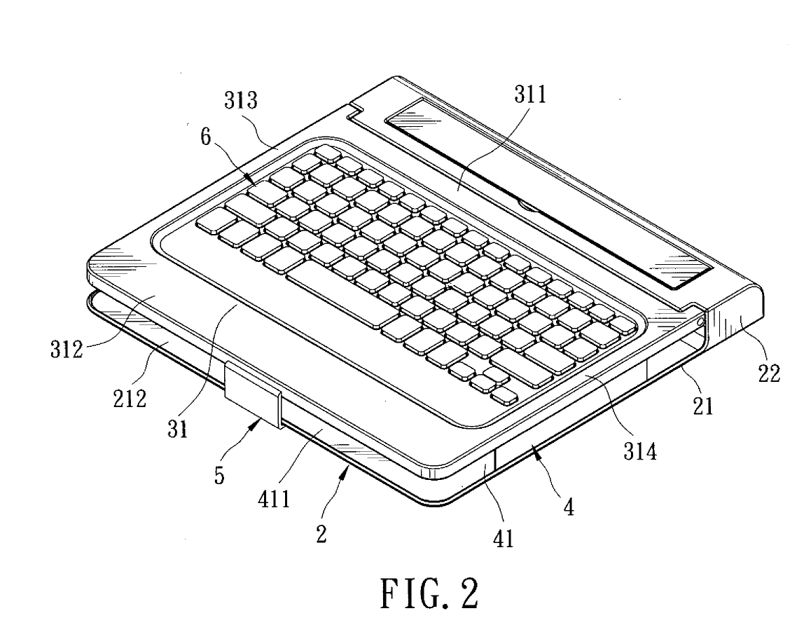

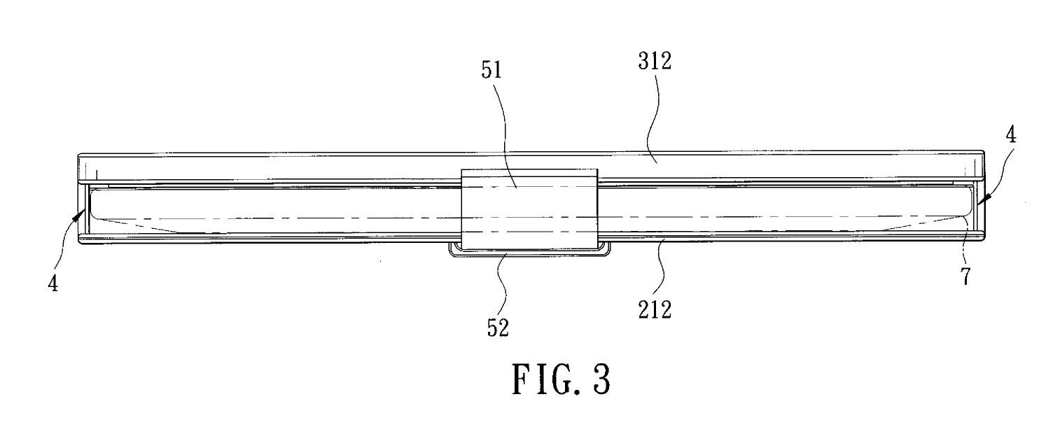

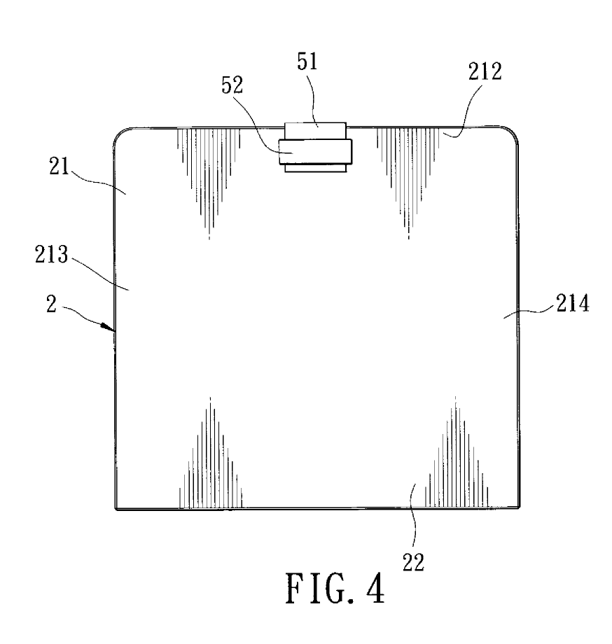

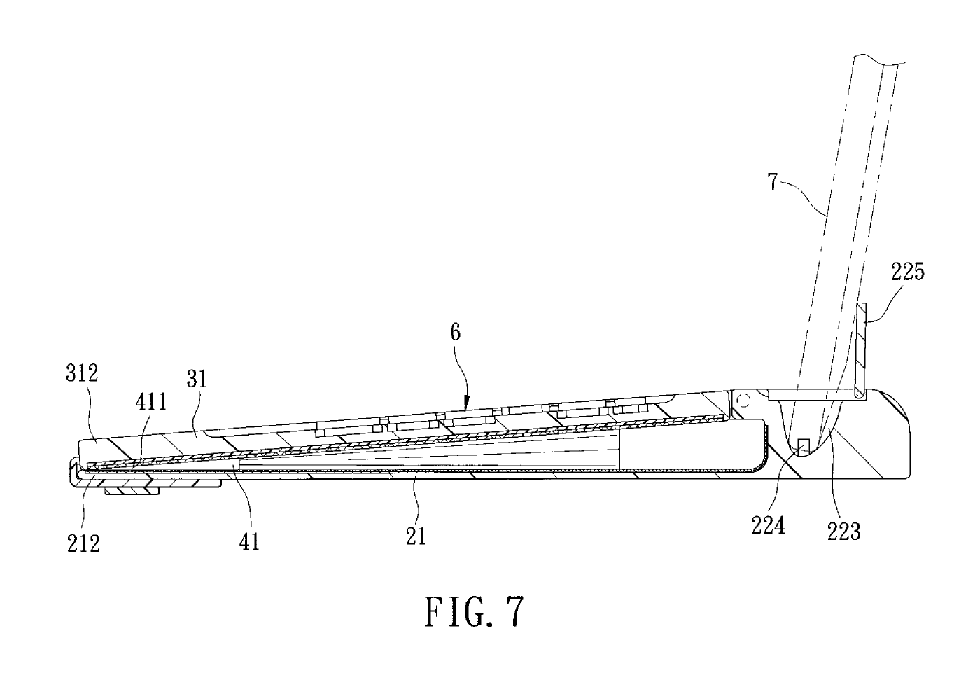

Referring to FIGS. 2 to 5, the preferred embodiment of a protective device for an electronic apparatus of the present invention comprises a base unit 2, a cover plate 31, two fence members 4, a fastening unit 5, and an input unit 6. Further referring to FIG. 7, the phantom lines shown in FIGS. 3, 5 and 7 represent an electronic apparatus 7, i.e., a tablet computer.

The base unit 2 includes a base plate 21 having a base front end portion 211 integral with a front block 22, a base rear end portion 212, a base left end portion 213, and a base right end portion 214.

The cover plate 31 is disposed above the base plate 21 and has a cover front end portion 311 swingably connected to the base unit 2 and disposed above the base front end portion 211, a cover rear end portion 312 disposed above the base rear end portion 212, a cover left end portion 313 disposed above the base left end portion 213, and a cover right end portion 314 disposed above the base right end portion 214. The cover plate 31 is swingable relative to the base unit 2 to move the cover rear end portion 312 toward or away from the base rear end portion 212.

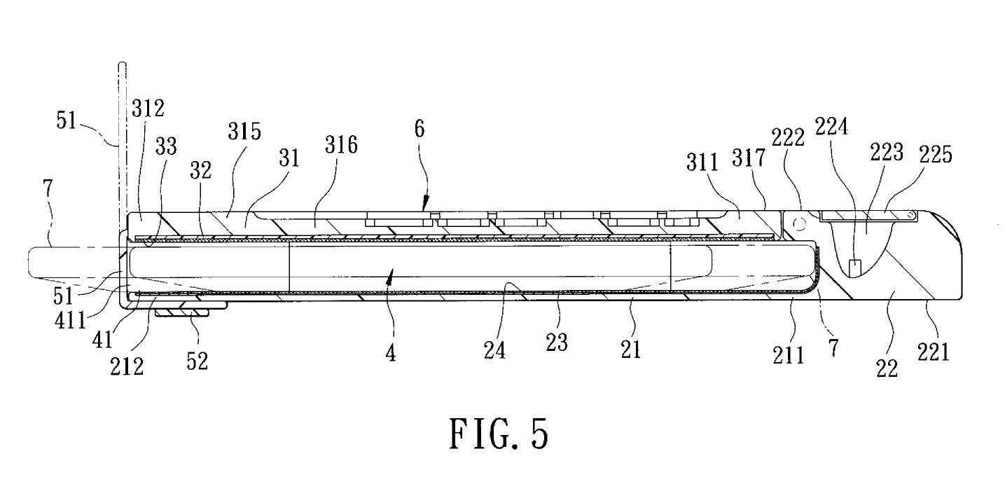

As shown in FIG. 5, the front block 22 of the base unit 2 has a bottom face 221 flush with the base front end portion 211 and atop face 222 substantially as high as the cover front end portion 311. In one preferred embodiment of the present invention, the front block 22 is further formed with a recess 223 indented downwardly from the top face 222, a socket 224 disposed in the recess 223 for electrical connection with the electronic apparatus 7, and a pivotable lid 225 covering the recess 223. The cover front end portion 311 of the top plate 31 is pivotably connected to the front block 22 near the top face 222, such that the cover plate 31 is pivotable relative to the base unit 2 to move the cover rear end portion 312 toward or away from the base rear end portion 212.

Regarding the two fence members 4, one of the fence members 4 is connected between the base and cover left end portions 213, 313, and the other is connected between the base and cover right end portions 219, 314. The two fence members 4 cooperate with the base plate 21 and the cover plate 31 to define a receiving space 41 that is for receiving the electronic apparatus 7 and that has an opening 411 between the base and cover rear end portions 213, 313 when the cover rear end portion 312 moves away from the base rear end portion 212.

In the preferred embodiment, the cover plate 31 includes a frame portion 315 disposed on an outer surface of the cover plate 31 opposite to the receiving space 41 and having a top frame surface 317, and a cave portion 316 surrounded by the frame portion 315 and indented downwardly from the top frame surface 317 of the frame portion 315 for mounting the input unit 6. In this embodiment, the base plate 21, the front block 22 and the cover plate 31 are preferably made from plastic materials.

The fastening unit 5 includes a fastening belt 51 connected to the cover rear end portion 312, and a fastening loop 52 connected to the base rear end portion 212. The cover rear end portion 312 is fastened to the base rear end portion 212 when the fastening belt 51 is passed through and tightened relative to the fastening loop 52. Alternatively, the fastening belt 51 can be connected to the base rear end portion 212, and the fastening loop 52 can be connected to the cover rear end portion 312.

The input unit 6 is disposed in the cave portion 316 of the cover plate 31. In this embodiment, the input unit 6 is a keyboard having a keyboard surface not higher than the top frame surface 317 of the frame portion 315 of the cover plate 31. Alternatively, the input unit 6 may be one of a touch pad, a track ball, a touch keyboard, and combinations thereof.

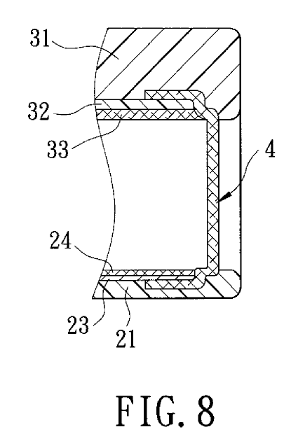

Preferably, as shown in FIG. 8, the protective device for an electronic apparatus according to the present invention further includes an upper reinforcing layer 32 and a lower reinforcing layer 23 disposed respectively on a lower surface of the cover plate 31 and on an upper surface of the base plate 21. The upper surface of the base plate 21 and the lower surface of the cover plate 31 face the receiving space 41. Preferably, the upper reinforcing layer 32 may be made from plastic materials, and the lower reinforcing layer 23 may be made from a metal.

Preferably, as shown in FIG. 8, the protective device of this invention further includes an upper cushion layer 33 and a lower cushion layer 29 that respectively cover the upper and lower reinforcing layers 32, 23. Preferably, the upper cushion layer 33 and the lower cushion layer 24 are both made from wool materials.

As shown in FIG. 8, the fence members 4 may be elastic bands. Each of the fence members 9 has a first end that is fixed between the cover plate 31 and the upper reinforcing layer 32, and a second end that is fixed between the base plate 21 and the lower reinforcing layer 23.

As shown in FIGS. 2 and 5, when the electronic apparatus 7 is received in the receiving space 41 of the protective device, the cover rear end portion 312 of the cover plate 31 may be swung relative to the base unit 2 to move the cover rear end portion 312 away from the base rear end portion 212 of the base plate 21, thereby enlarging the opening 411 of the receiving space 41 to allow the electronic apparatus 7 to be received in the receiving space 41 and be prevented from slipping out of the receiving space 41 by fixation arrangement of the fastening belt 51 and the fastening loop 52 of the fastening unit 5. Besides, in the receiving space 41, the electronic apparatus 7 is held between the cover plate 31 and the base plate 21 through the upper cushion and reinforcing layers 33, 32 and the lower cushion and reinforcing layers 24, 23. Thus, the electronic apparatus 7 can be protected from being scratched.

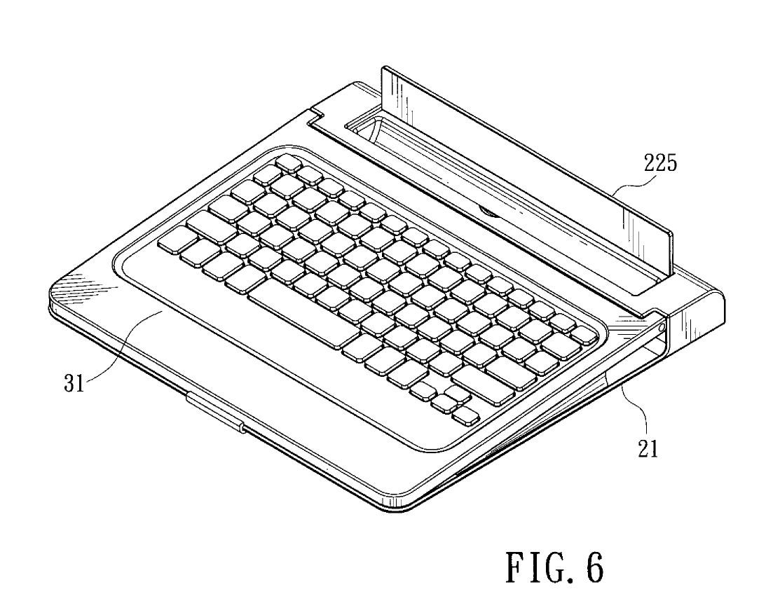

When the electronic apparatus 7 is taken out of the receiving space 41 and mounted in the socket 224 in the recess 223 of the front block 22 for electrically connecting to the input unit 6, as shown in FIGS. 6 and 7, the pivotable lid 225 is pivoted to away from the top face 222 of the front block 22 and serves as a backboard for supporting the electronic apparatus 7 at an angle suitable for the user's viewing. In addition, the cover rear end portion 312 may be swung relative to the base unit 2 to move the cover rear end portion 312 toward the base rear end portion 212 so that the receiving space 41 has a relatively small opening 411. The cover rear end portion 312 may be fastened to the base rear end portion 212 by passing the fastening belt 51 through the fastening loop 52 and tightening the fastening belt 51 relative to the fastening loop 52. Hence, the input unit 6 disposed in the cave portion 316 of the cover plate 31 may be inclined at an angle larger than 0 degree with respect to the horizontal plane so as to conform to ergonomics, and the vertically mounted electronic apparatus 7 becomes convenient for the user's viewing.

As an alternative embodiment, the socket 224 of the preferred embodiment can be replaced by a wireless module, such as a Bluetooth module (not shown), so as to wirelessly connect the electronic apparatus 7 to the input unit 6.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A protective device for an electronic apparatus, comprising:
abase unit including a base plate having a base front end portion, a base rear end portion, a base left end portion, and a base right end portion;
a cover plate disposed above said base plate, and including a cover front end portion connected swingably to said base unit and disposed above said base front end portion, a cover rear end portion disposed above said base rear end portion, a cover left end portion disposed above said base left end portion, and a cover right end portion disposed above said base right end portion, said cover plate being swingable relative to said base unit to move said cover rear end portion toward or away from said base rear end portion;
two fence members, one of which is connected between said base and cover left end portions and the other of which is connected between said base and cover right end portions, said fence members cooperating with said cover plate and said base plate to define a receiving space for receiving the electronic apparatus, said receiving space having an opening between said base and cover rear end portions when said cover rear end portion moves away from said base rear end portion; and
an input unit disposed on said cover plate.

2. The protective device of claim 1, wherein each of said fence members is an elastic band.

3. The protective device of claim 1, wherein said cover plate includes a frame portion opposite to said receiving space and having a top frame surface, and a cave portion for mounting said input unit, said cave portion being surrounded by said frame portion and being indented downwardly from said top frame surface of said frame portion.

4. The protective device of claim 3, wherein said input unit is a keyboard having a keyboard surface, said top frame surface being higher than said keyboard surface.

5. The protective device of claim 1, further comprising a fastening unit including a fastening belt connected to said cover rear end portion, and a fastening loop connected to said base rear end portion, said cover rear end portion being fastened to said base rear end portion when said fastening belt is passed through and is tightened relative to said fastening loop.

6. The protective device of claim 1, wherein said base unit further includes a front block integral with said base front end portion, said front block having a bottom face flush with said base front end portion, and a top face that is substantially as high as said cover front end portion, said cover front end portion being pivotably connected to said front block near said top face.

7. The protective device of claim 6, wherein said front block is formed with a recess that is indented downwardly from said top face.

8. The protective device of claim 7, wherein said front block further includes a pivotable lid covering said recess.

9. The protective device of claim 7, further comprising a socket disposed in said recess for an electrical connection with the electronic apparatus.

10. The protective device of claim 1, further comprising upper and lower reinforcing layers respectively disposed on an upper surface of said base plate and on a lower surface of said cover plate, said upper surface of said base plate and said lower surface of said cover plate facing said receiving space, said protective device further comprising upper and lower cushion layers respectively covering said upper and lower reinforcing layers, each of said fence members having a first end that is fixed between said cover plate and said upper reinforcing layer, and a second end that is fixed between said base plate and said lower reinforcing layer.
